(19) United States
(12) Patent Application Publication
(10) Pub. No.: US 2009/0229667 A1
(43) Pub. Date: Sep. 17, 2009

(54) TRANSLUCENT SOLAR CELL

(75) Inventors: Vishal Shrotriya, El Monte, CA (US); Gang Li, El Monte, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(73) Assignee: SOLARMER ENERGY, INC., El Monte, CA (US)

(21) Appl. No.: 12/049,252

(22) Filed: Mar. 14, 2008

(51) Int. Cl. H01L 31/0256; H01L 31/06; H01L 31/18

(52) U.S. Cl. 136/263; 427/74; 427/109; 438/82; 257/E31.003

(57) ABSTRACT

A translucent solar cell has a transparent substrate and a first translucent electrode that is in anode. A transparent active layer, that is a substantially organic material layer, is formed on top of the anode. On top of the active layer, a second translucent electrode is formed. The second translucent electrode is the cathode. In a variation, the first translucent electrode is the cathode and the second translucent electrode the anode. The flexibility in choosing the order of the anode and cathode relative to the transparent substrate allows for an increase in processing techniques and, thus, the amount of utilizable materials to increase the power conversion efficiency of translucent solar cells.

### BACKGROUND

1. Field

This disclosure relates, in general, to solar cells.

2. General Background

Solar cells made from organic materials and polymers are considered as promising alternatives to their inorganic counterparts. Ever since their first report, polymer/fullerene bulk-heterojunction (BHJ) solar cells, more commonly known as plastic solar cells, have attracted a lot of positive attention.

### SUMMARY

A translucent solar cell has a transparent substrate and a first translucent electrode that is the anode. A transparent active layer, that is a substantially organic material layer, is formed on top of the anode. On top of the active layer, a second translucent electrode is formed. The second translucent electrode is the cathode. In a variation, the first translucent electrode is the cathode and the second translucent electrode is the anode. The flexibility in choosing the order of the anode and cathode relative to the transparent substrate allows for an increase in processing techniques and, thus, the amount of utilizable materials to increase the power conversion efficiency of translucent solar cells.

Translucent solar cells have a low cost for their raw material and their manufacturing. From a raw material point of view, a polymer is derived from organic elements having great abundance and availability. From a manufacturing point of view, the solar cells utilize solution processing, thus yielding an easier fabrication process that requires less energy input than their silicon or other inorganic counterparts.

### DRAWINGS

The above-mentioned features and objects of the present disclosure will become more apparent with reference to the following description taken in conjunction with the accompanying drawings wherein like reference numerals denote like elements and in which:

FIG. 1 is an exemplary embodiment of a translucent solar cell.

FIG. 2 is an exemplary embodiment of a translucent solar cell.

FIG. 3 is a process flow diagram for a method of making a translucent solar cell in accordance with the present disclosure.

FIG. 4 is a process flow diagram for a method of making a translucent solar cell in accordance with the present disclosure.

FIG. 5 is a process flow diagram for a method of making a translucent solar cell in accordance with the present disclosure.

FIG. 6 is a process flow diagram for a method of making a translucent solar cell in accordance with the present disclosure.

FIG. 7 is a process flow diagram for a method of making a translucent solar cell in accordance with the present disclosure.

FIG. 8 is a process flow diagram for a method of making a translucent solar cell in accordance with the present disclosure.

FIG. 9 is a table showing various solar cell properties after annealing at different temperatures, in accordance with the present disclosure.

FIG. 10 is a curve that shows improved performance of polymer solar cells upon thermal annealing, in accordance with the present disclosure.

FIG. 11 is a schematic of multiple device tandem structure solar cells, in accordance with the present disclosure.

### DETAILED DESCRIPTION

Polymer active layers used in plastic solar cells are usually about 50-200 nm thick. This small thickness results in inefficient absorption because the maximum absorption wavelength for a polymer active layer is usually about 650 nm. For example, maximum absorption in a 80 nm thick poly(3-hexylthiophene): [6,6]-phenyl C₆₁-butyric acid methyl ester (P3HT:PCBM) film, the most commonly used active layer, has been shown to be less than 40% at the peak absorption wavelength. At other wavelengths in the absorption range an even higher percentage of light is transmitted without being absorbed.

The active layer of the plastic solar cells is semi-transparent or translucent in the visible light range. This semi-transparent or translucent property of the active layer can be used to the advantage of fabricating translucent plastic solar cells. In order to make the plastic solar cells translucent, the bottom and top contacts have to be made semi-transparent. The photons that are unabsorbed in the active layer should be transmitted through the cell, without any significant reduction in intensity.

The present disclosure makes use of the following processes described herein:

Thermal annealing: Thermal annealing is a process in which the substrates, which have various layers deposited on top, are provided thermal energy (heat) by placing the substrates on a hot plate, which is maintained at a certain temperature for a certain period of time. The temperature is referred to as the annealing temperature and the time as annealing time. The thermal annealing may also be done by providing the thermal energy in non-contact mode where the substrate does not come in contact with the hot plate (or heat source), such as placing the substrates in an oven under controlled temperature for a certain period of time.

Solvent annealing: Solvent annealing is a process where an organic layer, which has been deposited on top of a substrate that has a bottom contact deposited by solution processing, is allowed to solidify at a controlled slow rate to enhance the self-organization in the organic polymer film. This is achieved by dissolving the organic polymer(s) in a high boiling point solvent, such as dichlorobenzene or tricholorobenzene, for depositing the organic polymer film by solution processing. Due to the high boiling point of the solvent, the film is usually wet after it is deposited, which is then allowed to dry in a controlled manner to slow down the time it takes for the film to convert from liquid phase to solid phase. The desired solidification time is between 2 to 20 minutes. The longer solidification time allows the polymer chains in film to align in a highly-ordered crystalline phase which may result in increased efficiency of photovoltaic conversion in the film.

Adding additives to enhance carrier mobility: Adding additives is a technique used in polymer solar cells to improve the morphology and enhance the carrier mobility. One example is adding slight amount of poor solvent(s) (e.g. alkanedithiols, or nitrobenzene) into the dominant solvent used to make polymer solution (e.g. chlorobenzene or dichlorobenzene). Improved polymer aggregation and crystallinity has been achieved in some polymer systems and so has enhanced carrier mobility. Another example is the addition of electrolytes and salt into polymer blend solutions, which is also shown to improve photocurrent in polymer solar cells.

Thermal evaporation: Thermal evaporation is a common technique, one of the physical vapor deposition (PVD) methods, to deposit thin film materials. In thermal evaporation, the material is heated in a vacuum of 10⁻⁵ to 10⁻⁷ Torr range until it melts and starts evaporating. The vapor then condenses on a substrate exposed to the vapor, which is kept at a cooler temperature to form a thin film. The materials are heated by placing them in a crucible (or boat) which is made of high electrical resistance material such as tungsten, and passing high current through the boat.

Device Structure and Fabrication

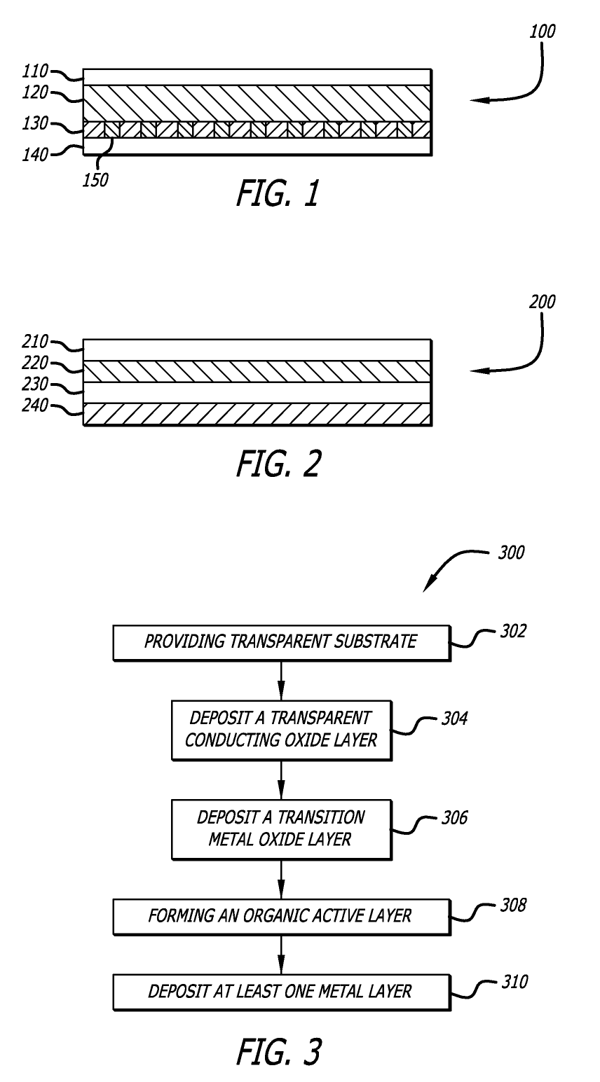

The solar cell device structure, shown in FIG. 1, comprises an active layer 120 which absorbs sunlight and converts it into electricity. The active layer 120 is between two contacts 110 and 130, both of which are semi-transparent or translucent and built on a transparent substrate 140. The translucent solar cell can absorb sunlight from both sides, from the top or the bottom. The device may further include a metal mesh 150 to provide a high surface conductivity and to increase charge collection efficiency.

Based on the polarity of the cell, two configurations are possible: (i) regular device structure, and (ii) inverted device structure. In the regular structure the bottom contact is the anode 130, which collects holes, and the top contact is the cathode 110 which collects electrons during the energy conversion process, as shown in FIG. 1. The polarity is reversed in the inverted cell configuration, as shown in FIG. 2, the bottom contact is the cathode 230 and top contact is the anode 210.

Active Layer

The active layer 120 is typically a bulk-hetero-junction (BHJ) of a p-type donor polymer and an n-type acceptor material. In the donor polymer, the photons are absorbed and the excitons are generated upon photo-absorption. The generated excitons migrate to the donor-acceptor interface, where they are dissociated into free electrons and holes, which are then transported through a 3-dimensional (3-D) interpenetrated network of donors and acceptors in the BHJ film and are collected at the contacts. Many polymers can be used as the donor in the BHJ film, such as P3HT, poly[2-methoxy-5-(3,7-dimethyloctyloxy)-1,4-phenylene vinylene] (MDMO-PPV), or poly(2-methoxy-5-(2′-ethyl-hexyloxy)-1,4-phenylene vinylene) (MEH-PPV). Other low-band-gap polymers can be used for the active layer as well.

By selecting the polymer, the color and transparency can be adjusted for specific applications. The most common candidate for the acceptor materials are PCBM or [6,6]-phenyl C₇₁-butyric acid methyl ester (C₇₀-PCBM). Other materials such as single-walled carbon nanotubes (CNTs) and other n-type polymers can also be used as the acceptor material as well. The active layer can be obtained by spin-coating from polymer solution in organic solvent(s). The film can also be obtained by several other solution processing techniques, such as bar-coating, inkjet-printing, doctor-blading, spray coating, screen printing etc. By using these techniques, a large area of substrate can be covered by a polymer solution with ease and without compromising the cost of the process. Also, flexible substrates can be used to substitute glass, resulting in a translucent and flexible plastic solar cell.

To improve the photovoltaic conversion efficiency of the plastic solar cell, the BHJ film may undergo specific treatments. For example, in P3HT:PCBM system, both so called “solvent annealing” approach and thermal annealing approach can be used. In the “solvent annealing” approach, the slow solidification rate of the active layer 120 allows the P3HT polymer chains to be organized into a highly ordered crystalline state, which improves the absorption of light within the polymer, enhances the charge carrier mobility, improves the exciton generation and dissociation efficiency, and results in a highly balanced charge carrier transport. Due to these effects the efficiency of plastic solar cells can be enhanced significantly. Thermal annealing has also been used to partially recover the polymer crystallinity as well as to improve the solar cell performance. Other possible approaches may include solvent mixing, where two or more solvents are used to dissolve the polymer blend, which is used to prepare the active layer 210, or by adding an ionic salt into the active layer 120, as well as other potential interfacial layer modifications known in the art.

Regular Device Structure

In a regular device configuration 100, shown in FIG. 1, the active layer 120 is sandwiched between semi-transparent bottom (anode) 130 and top (cathode) 110 electrodes.

The regular device structure of the translucent solar cell 100 has a transparent substrate 140 and a translucent anode 130 on top of the substrate 140. The anode 130 can be provided with a volume and a metallic mesh 150 embedded within the volume.

The translucent solar cell 100 has a transparent active layer 120 made of a substantially organic material and a translucent cathode 110. The active layer 120 lies between the translucent anode 130 and the translucent cathode 110.

Bottom Contact

A transparent conductive oxide (TCO), indium tin oxide (ITO), fluorinated tin oxide (FTO) can be deposited on a coated glass (or plastic) substrates to form the transparent anode 130. The TCO films are obtained by solution processing, sputtering or thermal spray-coating. To enhance the performance of the organic solar cells, the TCO covered glass surface is coated with a thin layer of high conductivity polymer, such as poly(ethylenedioxythiophene): poly(styrenesulfonate) (PEDOT:PSS), or polyaniline (PANI).

In another variation, to form the bottom transparent electrode 130, the TCO is covered with a thin layer of transition metal oxides (TMOs), such as vanadium pentoxide (V₂O₅), molybdenum oxide (MoO₃), or tungsten oxide (WO₃). In this case, the metal oxides are either thermally evaporated or deposited through solution processes directly on top of TCO glass substrates, and form the anodic interfacial layer. The TMO layer, with a thickness of 3-20 nm, can replace PEDOT:PSS in the polymer solar cells without effecting the performance since it is transparent and reasonably conductive. The efficiency of polymer solar cells with a TCO/TMO bottom contact is comparable to or even better than those with a ITO/PEDOT:PSS bottom contact. Using TMO as the anode interfacial layer also prevents the unwanted chemical reaction between ITO and PEDOT:PSS, which can cause performance degradation resulting in poor organic solar cell lifetime.

Conductive polymers, such as PEDOT:PSS or PANI, can substitute the TCO layer as the bottom transparent electrode 130. Since conducting polymers can be solution processed, this method results in an easy and low cost process that gets rid of high temperature deposition process such as sputtering of TCOs. However, the conductivity of even highest conductivity PEDOT is only about 100 S/cm, which is about an order of magnitude lower than that of ITO. To achieve efficient charge collection, the conductivity must be improved. To overcome this deficiency, very fine metal lines or mesh 150 are embedded into the PEDOT:PSS or PANI film to provide high surface conductivity and efficient charge collection at the interface. The metal lines are thermally evaporated on top of glass substrates though a photo-mask prepared by photo-lithography. Several high conductivity metals such as aluminum (Al), gold (Au), silver (Ag), copper (Cu), chromium (Cr) coated with Au, etc. can be used for metal lines 150. The high conductivity polymer film can be deposited from aqueous solution on glass substrates covered with metal lines, evaporated on top of the glass substrates, by using solution processing techniques, such as spin-coating, bar-coating, inkjet-printing, doctor-blading, spray coating, screen printing or other techniques known in the art.

Top Contact

The top contact 110 in the regular device structure has to be transparent. This transparent cathode 110 has to fulfill two functions. It allows the light that is not absorbed by the active layer 120 to be transmitted effectively and enables efficient electron collection at the cathode-polymer interface at the same time.

One of the methods for obtaining a semi-transparent cathode 110 is thermally evaporating multi-layered metals films. Such multi-layered metal films include: (i) lithium fluoride (LiF) and Au, (ii) LiF and Al, (iii) calcium (Ca) and Au, and (iv) LiF, Al, and Au. The total thickness of the multi-layered metal cathode is about 10-12 nm. The metal films are evaporated under high vacuum in succession. The transmittance of metal electrode is about 80-85%.

In one instance, a semi-transparent top electrode 110 is obtained is by spin-coating a thin layer of n-type material such as cesium carbonate, calcium acetylacetonate [Ca(acac)₂], cesium fluoride (CsF), CNTs, followed by evaporating a thin layer of transparent metal such as Ag or Au. The thickness of the metal layer, in this case, would be about 15 nanometers or less.

Another way to obtain a semi-transparent top electrode 110 is to spin-coat a thin layer of n-type material such as cesium carbonate, calcium acetylacetonate [Ca(acac)₂], cesium fluoride (CsF), CNTs, etc. followed by depositing a transparent conducting oxide layer, such as ITO or FTO, by sputtering or thermal spray-coating to form the semi-transparent top electrode 110.

A method for fabricating a translucent solar cell 100 is represented as process flow operations 300 in FIG. 3. The method comprises providing a transparent substrate at initialization operation 302. Control then transfers to operation 304.

In operation 304, a transparent anode 130 is formed on the transparent substrate 140. The transparent anode 130 is formed of a transparent conducting oxide layer deposited on the transparent substrate 140. In the present disclosure, the conducting oxide layer of the anode 130 can be, but is not limited to indium tin oxide or fluorinated tin oxide and can be either sputtered or thermal spray-coated onto the substrate 140. Control then transfers to operation 306.

In operation 306, a transition metal oxide layer is deposited on the transparent conducting oxide layer of the transparent anode by solution processing. The transition metal oxide layer has a work function substantially similar to a lowest unoccupied molecular orbital level of the organic active layer 120 and can be, but is not limited to vanadium pentoxide, molybdenum oxide, or tungsten oxide, in accordance with the present disclosure. Control then transfers to operation 308.

In operation 308, an organic active layer 120 is formed on the transparent anode 130. The organic active layer 120 has a mix of donor and acceptor molecules. Forming the organic active layer may further comprise thermal annealing, solvent annealing or adding additives for enhancing carrier mobility, where the transparent substrate 140, transparent anode 130 and the organic active layer 120 are treated within a temperature range of about 70-180 Celsius, in accordance with the present disclosure. Control then transfers to operation 310.

In final operation 310, a transparent cathode 110 is evaporated on top of the organic active layer 120. The transparent cathode 110 is made of at least one metal layer and has a thickness less than 20 nanometers. The metal layer(s) of the cathode 110 can be lithium fluoride and gold, lithium fluoride and aluminum, calcium and gold, and cesium fluoride and gold, cesium fluoride and aluminum, cesium carbonate and gold, and cesium carbonate and aluminum, lithium fluoride and gold, and aluminum and gold.

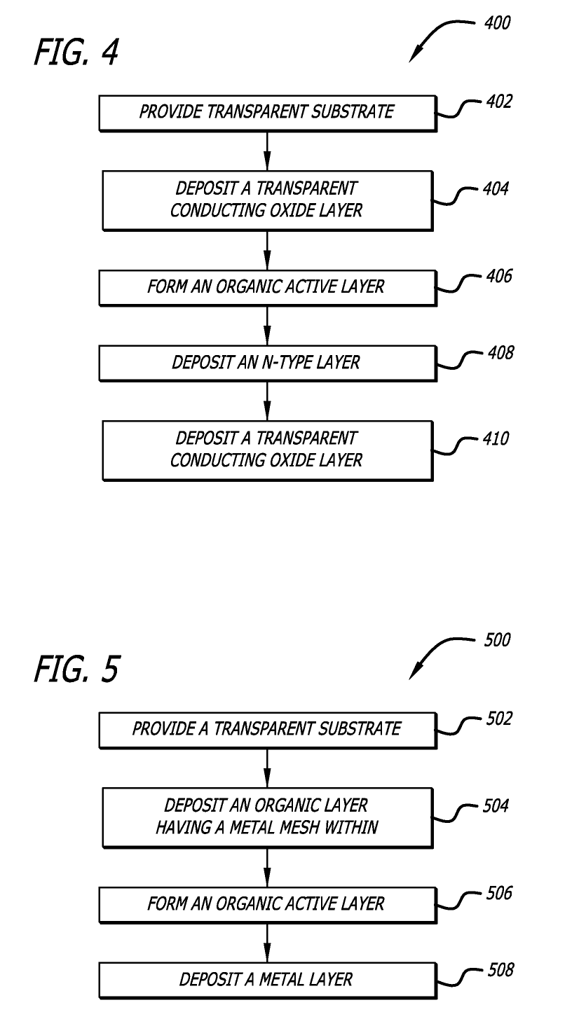

FIG. 4 represents process flow operations 400 for fabricating a translucent solar cell 100. The method comprises providing a transparent substrate at initialization operation 402. Control then transfers to operation 404.

In operation 404, a transparent anode 130 is formed on the transparent substrate 140. The transparent anode 130 is formed of a transparent conducting oxide layer deposited on the transparent substrate 140. The conducting oxide layer of the anode 130 can be indium tin oxide and fluorinated tin oxide and can be either sputtered or thermal spray-coated onto the substrate 140, in accordance with the present disclosure.

Additionally, a transition metal oxide layer may be deposited by solution processing on the transparent conducting oxide layer of the transparent anode 130. The transition metal oxide layer preferably has a work function that is substantially similar to a lowest unoccupied molecular orbital level of the organic active layer 120. The transition metal oxide can be, but is not limited to vanadium pentoxide, molybdenum oxide, or tungsten oxide, in accordance with the present disclosure. Control then transfers to operation 406.

In operation 406, an organic active layer 120 is formed on the transparent anode 130. The organic active layer 120 has a mix of donor and acceptor molecules. Forming the organic active layer may further comprise thermal annealing, solvent annealing, or adding additives for enhancing carrier mobility, where the transparent substrate 140, transparent anode 130 and the organic active layer 120 are treated within a temperature range of about 70-180 Celsius. Control then transfers to operation 408.

In operation 408, a transparent cathode 110 is formed on top of the organic active layer. The transparent cathode 110 can be made of at least an n-type layer that can be deposited by solution processing and preferably has a work function that is substantially similar to a lowest unoccupied molecular orbital energy level of the organic active layer. The n-type layer can be, but is not limited to cesium carbonate, calcium acetylacetonate, or cesium fluoride. Control then transfers to operation 410.

In final operation 410, a transparent conducting oxide layer is deposited on the n-type layer of the transparent cathode 110 by either sputtered or thermal spray-coating. The conducting oxide layer can be, but is not limited to indium tin oxide or fluorinated tin oxide.

Alternately, in final operation 410, a metal layer consisting of either Ag or Au, having a thickness less than 15 nanometers, can be deposited by thermal evaporation on top of the n-type layer of the transparent cathode 110.

FIG. 5 represents process flow operations 500 for fabricating a translucent solar cell 100. The method comprises providing a transparent substrate at initialization operation 502. Control then transfers to operation 504.

In operation 504, an anode 130 is formed on the transparent substrate 140. The anode 130 is an organic layer deposited by a solution processing. The organic layer has a volume and a metal mesh 150 embedded in the volume. The metal mesh 150 can be, but is not limited to gold, aluminum, silver, copper, or chromium coated with gold. Control then transfers to operation 506.

In operation 506, an organic active layer 120 is formed on the transparent anode 130. The organic active layer 120 has a mix of at least one type of donor and at least one type of acceptor molecule.

Additionally, the organic active layer 120 may further comprise thermal annealing, solvent annealing or adding additives to enhance carrier mobility. The transparent substrate 140, transparent anode 130 and the organic active layer 120 can be treated within a temperature range of about 70-180 Celsius. Control then transfers to operation 508.

In final operation 508, a transparent cathode 110 is formed on the organic active layer 120. The transparent cathode 110 is at least one metal layer having a thickness less than 20 nanometers and can be, but is not limited to lithium fluoride and gold, lithium fluoride and aluminum, calcium and gold, and cesium fluoride and gold, cesium fluoride and aluminum, cesium carbonate and gold, and cesium carbonate and aluminum, lithium fluoride and gold, or aluminum and gold.

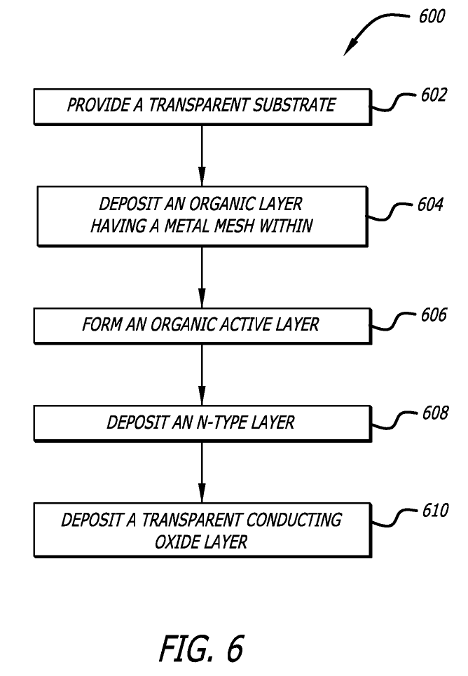

FIG. 6 represents process flow operations 600 for fabricating a translucent solar cell 100. The method comprises providing a transparent substrate at initialization operation 602. Control then transfers to operation 604.

In operation 604, an anode 130 is formed on the transparent substrate 140. The anode 130 is an organic layer deposited by solution processing. The organic layer has a volume and a metal mesh 150 embedded in the volume. The metal mesh 150 can be, but is not limited to gold, aluminum, silver, copper, or chromium coated with gold. Control then transfers to operation 606.

In operation 606, an organic active layer 120 is formed on the transparent anode 130. The organic active layer 120 preferably has a mix of at least one type of donor and at least one type of acceptor molecule.

Additionally, the organic active layer 120 may further comprise thermal annealing, solvent annealing, or adding additives to enhance carrier mobility. The transparent substrate 140, transparent anode 130 and the organic active layer 120 can be treated within a temperature range of about 70-180 Celsius. Control then transfers to operation 608.

In operation 608, a transparent cathode 110 is formed on top of the organic active layer. The transparent cathode 110 is made of at least an n-type layer that can be deposited by solution processing and preferably has a work function that is substantially similar to a lowest unoccupied molecular orbital energy level of the organic active layer. The n-type layer can be, but is not limited to cesium carbonate, calcium acetylacetonate, or cesium fluoride. Control then transfers to operation 410.

In final operation 610, a transparent conducting oxide layer is deposited on the n-type layer of the transparent cathode 110 by either sputtered or thermal spray-coating. The conducting oxide layer can be, but is not limited to indium tin oxide or fluorinated tin oxide.

Alternately, in final operation 610, a metal layer consisting of either Ag or Au, and having a thickness less than 15 nanometers, can be deposited by thermal evaporation on top of the n-type layer of the transparent cathode 110.

Inverted Device Structure

In the inverted device configuration 200, the bottom contact 230 is the cathode where the electrons are collected and the top contact is the anode 210 where holes are collected during photovoltaic generation. Both of the contacts are again semi-transparent.

An inverted transparent solar cell 200 is shown in FIG. 2. The inverted solar cell 200 comprises a transparent substrate 240 having a bottom surface and a top surface.

A first translucent electrode, the cathode 230, is on the top surface of the substrate 240 and made of a transparent conductive oxide. The cathode 230 is formed of a transparent conducting oxide with an n-type interfacial layer.

A second translucent electrode, the anode 210, is made of a transparent conductive oxide and has an interfacial layer. A transparent active layer 220 is made of a substantially organic material and is between the translucent anode 210 and the translucent cathode 230.

Bottom Contact

The role of the bottom contact 230, the cathode, is to collect free electrons that are generated in the active layer 220 during photovoltaic conversion process. To achieve efficient electron collection several options can be used. Examples are given below.

A thin layer of an n-type material such as CsCO₃, CsF, Ca(acac)₂, CNT, or other materials with similar properties can be spin-coated on a TCO covered glass or plastic substrate 240 to achieve a transparent bottom cathode 230, as shown in FIG. 2. The thickness of all these cathode interfacial layers is very small, only a few nanometers, and as a result, they are highly transparent. The work function of ITO is about 4.7 eV, which makes it a hole transport material. Therefore, the ITO surface has to be modified with a thin n-type interfacial layer, as mentioned above, to make it an electron collecting contact. For example, the work function of CsCO₃ is about 2.9 eV.

The ITO or FTO coated glass or plastic substrate 240 can be coated with a thin layer of titanium oxide (TiOx), zinc oxide (ZnO), or ZnO:Al and other electron transport materials, to achieve a transparent bottom cathode 230. The thickness of the oxide layer in this case is about 10-20 nm.

Top Contact

The top contact 210, the anode, collects the holes in the inverted device configuration. For the top contact 210, several configurations may be used.

The first configuration is comprised of a high work function p-type interfacial layer coated with a high conductivity thin metal film. The materials used for p-type interfacial layer are transition metal oxides, such as V₂O₅, MoO₃, or WO₃. The thickness of the metal oxides are about 3-10 nanometers in order to maintain transparency. The oxide film can be obtained by thermal evaporation or solution processing, directly on top of the polymer film. Since the conductivity of metal oxides is not particularly good, an additional layer of high conductivity metal, such as Au, may be required to coat the metal oxide layer. The metal can be thermally evaporated and have a thickness usually not exceeding 15 nanometers, to maintain the transparency.

Another way to obtain top contact 210 is to deposit a transparent conducting oxide layer, such as ITO or FTO by sputtering or thermal spray-coating, in place of a high conductivity metal such as Au, since transparent conductive oxides have better transparency and comparable electrical conductivity.

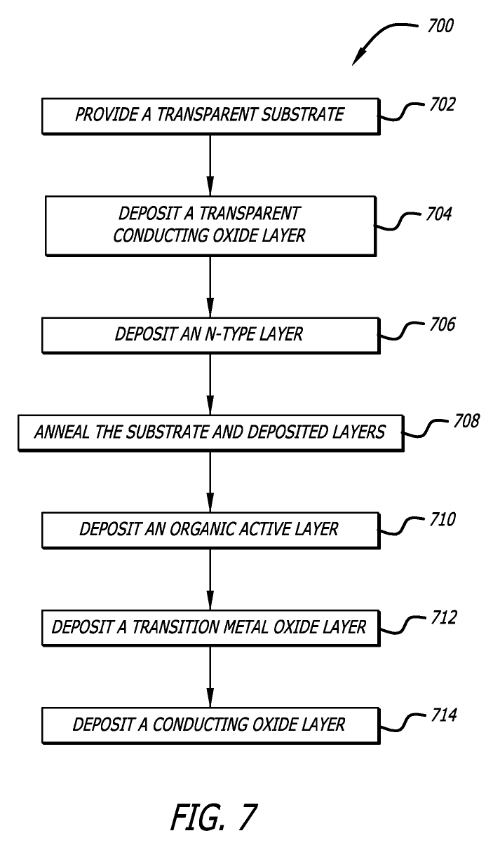

FIG. 7 represents process flow operations 700 for fabricating a translucent solar cell 200. The method comprises providing a transparent substrate 240 at initialization operation 702. Control then transfers to operation 704.

A transparent cathode 230 is formed on top of the transparent substrate 240. The forming process includes the steps of forming a transparent conducting oxide layer, in operation 704, and an n-type interfacial layer by solution processing, in operation 706 on the transparent substrate 240. In accordance with the present disclosure, the n-type layer can be, but is not limited to cesium carbonate, calcium acetylacetonate, or cesium fluoride. Control then transfers to operation 708.

In operation 708, the transparent substrate 240 and the transparent cathode 230 are thermally annealed within a temperature range of about 70-180° Celsius. Control then transfers to operation 710.

In operation 710, at least one organic active layer 220 is deposited on the transparent cathode 230. The organic active layer 220 can be deposited by solution processing and has a mix of donor and acceptor molecules. The organic active layer 220 has a lowest unoccupied molecular orbital energy level that is substantially similar to the n-type layer of the transparent cathode 230. Control then transfers to operation 712.

A transparent anode 210 is formed on the organic active layer 220, the forming process including the steps of depositing a transition metal oxide layer by solution processing, in operation 712. The transition metal oxide has a work function substantially similar to a highest occupied molecular orbital energy level of the organic active layer. The transition metal oxide layer of the anode 210 can be, but is not limited to vanadium pentoxide, molybdenum oxide, or tungsten oxide and is of a thickness less than 30 nanometers. Control then transfers to operation 714.

In operation 714, a transparent conducting oxide layer is deposited onto the transition metal oxide layer. The conducting oxide layer can be, but is not limited to indium tin oxide and fluorinated tin oxide or can be sputtered or thermal spray-coated onto the transparent substrate 240.

Alternately, in final operation 714, a metal layer of either Ag or Au, and having a thickness less than 15 nanometers, can be deposited by thermal evaporation on top of the transition metal oxide layer.

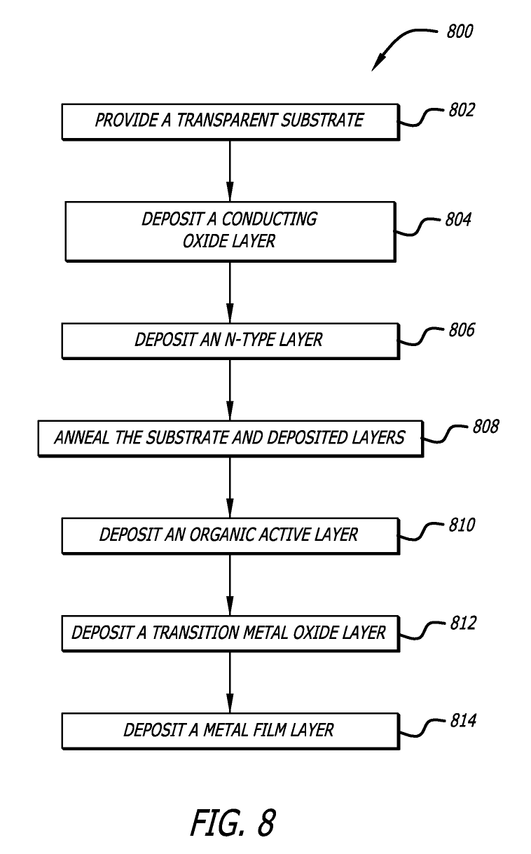

FIG. 8 represents process flow operations 800 for fabricating a translucent solar cell 200. The method comprises providing a transparent substrate 240 at initialization operation 802. Control then transfers to operation 804.

A transparent cathode 230 is formed on top of the transparent substrate 240. The forming process includes the steps of forming a transparent conducting oxide layer, in operation 804, and an n-type interfacial layer by solution processing, in operation 806 on the transparent substrate 240. The n-type layer can be at least cesium carbonate, calcium acetylacetonate, or cesium fluoride. Control then transfers to operation 808.

In operation 808, the transparent substrate 240 and the transparent cathode 230 are thermally annealed within a temperature range of about 70-180° Celsius. Control then transfers to operation 810.

In operation 810, at least one organic active layer 220 is deposited on the transparent cathode 230. The organic active layer 220 can be deposited by solution processing and has a mix of donor and acceptor molecules. The organic active layer 220 has a lowest unoccupied molecular orbital energy level that is substantially similar to the n-type layer of the transparent cathode 230. Control then transfers to operation 812.

A transparent anode 210 is formed on the organic active layer 220, the forming process including the steps of depositing a transition metal oxide layer by solution processing, in operation 812. The transition metal oxide has a work function substantially similar to a lowest unoccupied molecular orbital energy level of the organic active layer. The transition metal oxide layer of the anode 210 can be, but is not limited to vanadium pentoxide, molybdenum oxide, or tungsten oxide and is of a thickness less than 30 nanometers. Control then transfers to operation 814.

In final operation 814, at least one metal film is deposited on the transition metal oxide layer and can be, but is not limited to gold and silver.

In a variation, a thicker TMO film can be deposited on top of the polymer film, with thickness of about 20-50 nanometers. The large thickness of TMO does not have a significant effect of the device performance, while maintaining its interfacial properties. Once a comparatively thicker TMO film is deposited on the polymer film, it acts as a protective barrier for the polymer film. As a result a highly transparent conductive metal oxide, such as ITO or FTO may be evaporated or sputtered on top of TMO film to complete the device structure.

The work-function of Cs₂CO₃ can be modified from 3.45 eV to 3.06 eV by a low temperature (less than 200° C.) annealing treatment, verified by ultraviolet photoelectron spectroscopy (UPS). With the inverted device structure (ITO/Cs₂CO₃/RR-P3HT:PCBM/V₂O₅/Al), the PCE improves from 2.31% to 4.19% by a 150° C. thermal annealing treatment of the Cs₂CO₃ interfacial layer as shown in FIG. 10. Generally the decomposition temperature of Cs₂CO₃ is around 550-600° C. However, preliminary X-ray photoelectron spectroscopy (XPS) results reveal that thermal annealing helps Cs₂CO₃ decompose into a low-work function cesium-oxide. The lower work function of Cs₂CO₃ matches better with the lowest occupied molecular orbital level of the organic polymer, thereby increasing the efficiency of polymer solar cell.

0.2 wt % Cs₂CO₃ dissolved in 2-ethoxyethanol was spin-coated on pre-cleaned and UV-ozone-treated ITO glass substrates as the cathode 230. Various annealing temperatures were carried out on the hot plate inside the glove box for 20 minutes. RR-P3HT and PCBM were separately dissolved in 1,2-dichlorobenzene (DCB) then blended together with 1:1 wt/wt ratio to form a 2.5 wt % solution. This RR-P3HT/PCBM solution was spin-coated at 600 rpm for 40 seconds, and the wet film was dried in a covered glass Petri dish. The dried film was then annealed at 110° C. for 10 minutes.

The active film thickness was about 210-230 nanometers measured by a Dektak 3030 profilometer. The anode 210 is 10 nm V₂O₅ covered by 100 nm Al. The devices were tested in the glove box under simulated AM1.5G irradiation (100 mW/cm²) using a solar simulator. The illumination intensity was determined by a NREL calibrated Si-detector with KG-5 color filter, and the spectral mismatch was corrected.

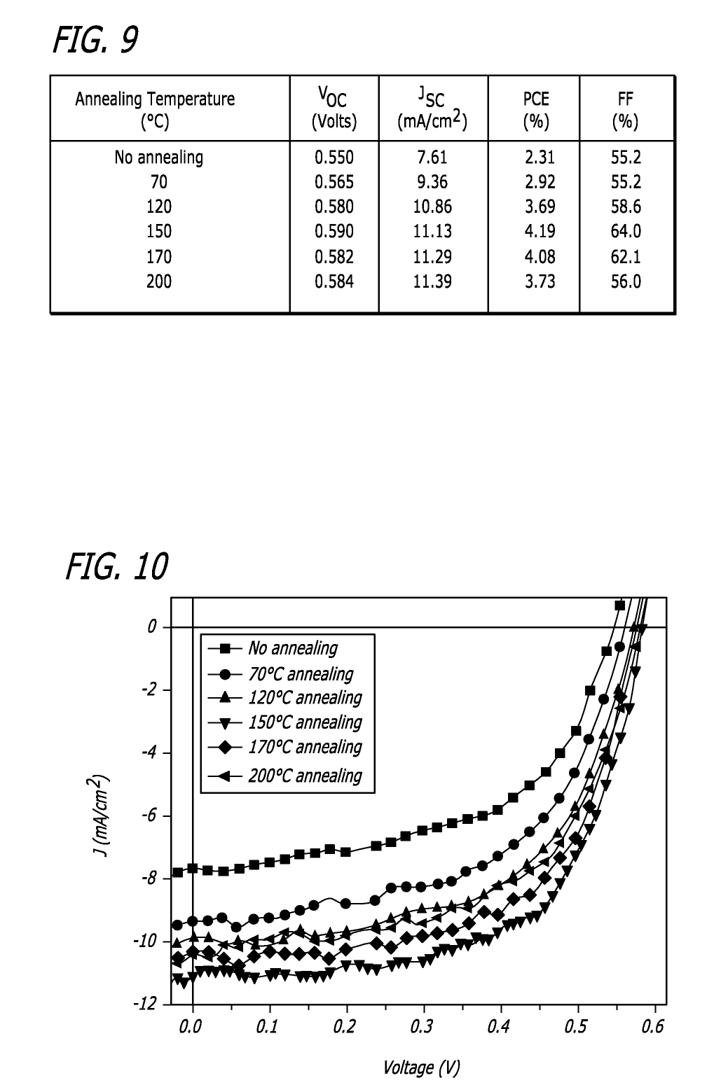

For the device without thermal annealing on Cs₂CO₃ layer, the power conversion efficiency (PCE) is 2.31%. When Cs₂CO₃ layers are treated by different temperature annealing process with different temperatures, all device performances improved. As the annealing temperature of the Cs₂CO₃ layer increased from room temperature to 150° C., the PCE increases from 2.31% to 4.19%. In addition, all other device characteristics, such as Voc, Jsc, and FF, improved as shown in FIG. 9 and FIG. 10.

The work-function of oxygen plasma-treated ITO substrate is 4.54 eV. When Cs₂CO₃ is spin-coated on this ITO surface without thermal annealing, the work-function changes from 4.54 eV to 3.23 eV. The work-function of the Cs₂CO₃ film further reduces to 3.13, 3.11, and 3.06 eV after annealing at 70° C., 120° C., and 170° C. for 20 minutes, respectively.

A highly efficient inverted polymer solar cell has been demonstrated by thermal annealing of a Cs₂CO₃ layer. The UPS results show that the work-function of the Cs₂CO₃ layer is decreased by thermal annealing, and preliminary XPS studies reveal that Cs₂CO₃ decomposes intrinsically into a doped n-type semiconductor by the annealing process. This inverted cell can be applied to design a multiple-device stacked polymer solar cells or a tandem cell, which are widely accepted to further improve the efficiency of polymer solar cells.

Multiple-Device Stacking Scheme—Beyond Tandem Solar Cell Structure

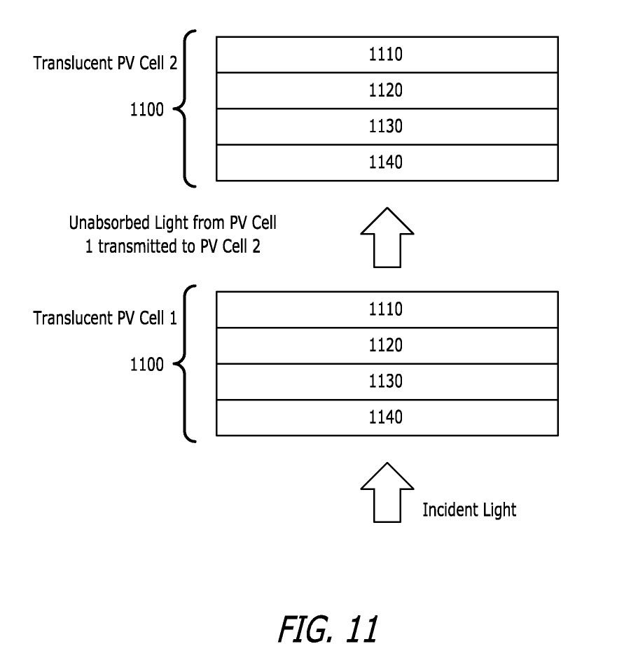

Utilizing photovoltaic materials to cover different regions of the solar spectrum is effective in improving solar cell efficiency. Tandem solar cell structure, where two or more cells are connected in series, can be demonstrated in a polymer solar cell. Translucent solar cells with different solar spectrum coverage can be used to realize tandem solar cells with enhanced photo-voltage. In this scheme, two individual PV cells, each having their own substrate, are stacked on top of each other, shown in FIG. 11. The cells are connected electrically in series or in parallel, which can up to double the efficiency of the stacked system compared to a single cell. The multiple-device stacking may also improve the yield of solar cells.

FIG. 11 is the schematic of a multiple-device tandem structure showing two translucent PV cells 1100 stacked on top of each other. The unabsorbed light from the first cell is transmitted to the second cell through transparent electrode 1110 in the bottom cell. This light is absorbed by PV cell 2. The PV cell 2 may or may not have a transparent top electrode 1110. The cells may be connected electrically in series or in parallel to increase the performance of the tandem structure compared to a single cell.

Incorporation of Reflectors or Diffuser

The translucent solar cell can also be used in the situation where transparency is not required. In these situations, a light reflector or diffuser can be used behind the translucent solar cell to reuse the light passing through. This can improve the efficiency of the translucent solar cell due to improved light harvesting.

A Few Applications of Translucent Plastic Solar Cell

Unlike their inorganic counterparts, translucent polymer solar cells are inherently unique, with distinctive characteristics that are suitable for untapped applications in the building and transportation industry. There are three key characteristics that distinguish organic solar cells from inorganic cells: architecturally aesthetic, versatile and flexible, and low-cost.

The translucent solar cells have the ability to create architecturally aesthetic applications by integrating them onto glass, glass laminates, or flexible substrates of virtually any building and transportation windows, thus allowing triple functions of power generation, light filtration, and architectural element/aviation, automotive, and marine design.

Some building applications may include the commercial, industrial, institutional (educational and governmental), and residential markets. Commercial and industrial markets encompass, but are not limited to, offices, hotels/motels, skyscrapers, factories, power plants, and warehouses. Institutional and residential markets are comprised of, but not limited to, colleges/universities, hospitals, government buildings, houses, apartment blocks, and condominiums. In the transportation industry, the polymer solar cells can fit into practically any type of transports with windows in air, rail, road, and water. In particular, we can integrate our translucent solar cells from commercial or military aircrafts to ground and water transportation such as passenger/commuter trains, automobiles, buses, trucks, ships, and boats.

While the apparatus and method have been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

1. A translucent solar cell comprising:
a transparent substrate;
a translucent anode being a substantially organic material on top of the substrate, the anode having a volume and a metallic mesh embedded within the volume;
a transparent active layer being a substantially organic material; and
a translucent cathode, wherein the active layer is between the translucent anode and the translucent cathode.

2. The translucent solar cell of claim 1, wherein the metallic mesh is at least gold, aluminum, silver, copper, or chromium coated with gold.

3. A method for fabricating translucent solar cells, the method comprising:
providing a transparent substrate;
forming a transparent anode on the transparent substrate, wherein the transparent anode is a transparent conducting oxide layer deposited on the transparent substrate;
forming an organic active layer on the transparent anode, the organic active layer having a mix of donor and acceptor molecules; and
forming a transparent cathode on top of the organic active layer by evaporation, wherein the transparent cathode is at least one metal layer having a thickness less than 20 nanometers.

4. The method of claim 3, wherein the at least one metal layer is at least lithium fluoride and gold, lithium fluoride and aluminum, calcium and gold, cesium fluoride and gold, cesium fluoride and aluminum, cesium carbonate and gold, cesium carbonate and aluminum, triple-layered lithium fluoride, and or aluminum and gold.

5. The method of claim 3, wherein the conducting oxide layer is at least indium tin oxide or fluorinated tin oxide and wherein the conducting oxide layer is at least sputtered or thermal spray-coated onto the substrate.

6. The method of claim 3, further comprising depositing a transition metal oxide layer by solution processing on the transparent conducting oxide layer of the transparent anode, wherein the transition metal oxide layer has a work function substantially similar to a highest occupied molecular orbital level of the organic active layer, and wherein the transition metal oxide is at least vanadium pentoxide, molybdenum oxide or tungsten oxide.

7. The method of claim 3, wherein forming the organic active layer further comprises thermal annealing, solvent annealing or adding additives for improving morphology and enhancing carrier mobility, where the transparent substrate, transparent anode and the organic active layer are treated at a temperature range of about 70-180° Celsius.

8. A method for fabricating translucent solar cells, the method comprising:
providing a transparent substrate;
forming a transparent anode on the transparent substrate, wherein the transparent anode is a transparent conducting oxide layer deposited on the transparent substrate by at least solution processing or thermal evaporation;
forming an organic active layer on the transparent anode, the organic active layer having a mix of at least one type of donor and at least one type of acceptor molecules; and
forming a transparent cathode on top of the organic active layer, the transparent cathode is at least an n-type layer deposited by at least solution processing or thermal evaporation, and a transparent conducting oxide layer, the n-type layer having a work function substantially similar to a lowest unoccupied molecular orbital energy level of the organic active layer.

9. The method of claim 8, wherein the n-type layer is at least cesium carbonate, calcium acetylacetonate, or cesium fluoride

10. The method of claim 8, wherein the conducting oxide layer is at least indium tin oxide or fluorinated tin oxide and wherein the conducting oxide layer is at least sputtered or thermal spray-coated on top of the n-type layer.

11. The method of claim 8, wherein forming the organic active layer further comprises thermal annealing, solvent annealing or adding additives to improve morphology and enhance carrier mobility, where the transparent substrate, transparent anode and the organic active layer are treated at a temperature range of about 70-180° Celsius.

12. The method of claim 8, further comprising depositing a transition metal oxide layer by solution processing on the transparent conducting oxide layer of the transparent anode, wherein the transition metal oxide layer has a work function substantially similar to a highest occupied molecular orbital level of the organic active layer, and wherein the transition metal oxide is at least vanadium pentoxide, molybdenum oxide or tungsten oxide.

13. The method of claim 8 further comprising evaporating at least one metal layer on top of the n-type layer wherein the metal layer is at least gold or silver and is less than 20 nanometers thick.

14. A method for fabricating translucent solar cells, the method comprising:
providing a transparent substrate;
forming an anode on the transparent substrate having an organic layer deposited by a solution process, the organic layer having a volume and a metal mesh embedded in the volume;
forming an organic active layer on the transparent anode, the organic active layer having a mix of at least one type of donor and at least one type of acceptor molecules; and
forming a transparent cathode onto the organic active layer by evaporation, wherein the transparent cathode is made of at least one metal layer having a thickness less than 20 nanometers.

15. The method of claim 14, wherein the metallic mesh is at least gold, aluminum, silver, copper, or chromium coated with gold.

16. The method of claim 14, wherein the at least one metal layer is at least lithium fluoride and gold, lithium fluoride and aluminum, calcium and gold, and cesium fluoride and gold, cesium fluoride and aluminum, cesium carbonate and gold, cesium carbonate and aluminum, triple-layered lithium fluoride, and or aluminum and gold.

17. The method of claim 14, wherein forming the organic active layer further comprises thermal annealing, solvent annealing or adding additives to improve morphology and enhance carrier mobility, where the transparent substrate, transparent anode and the organic active layer are treated within a temperature range of about 70-180° Celsius.

18. A method for fabricating translucent solar cells, the method comprising:
providing a transparent substrate;
forming an anode on the transparent substrate having an organic layer deposited by a solution process, the organic layer having a volume and a metal mesh embedded in the volume;
forming an organic active layer on the transparent anode, the organic active layer having a mix of at least one type of donor and at least one type of acceptor molecules; and
forming a transparent cathode onto the organic active layer by evaporation, wherein the transparent cathode is at least an n-type layer deposited by solution processing or thermal evaporation, and a transparent conducting oxide layer, the n-type layer having a work function being substantially similar to a lowest unoccupied molecular orbital energy level of the organic active layer.

19. The method of claim 18, wherein the metallic mesh is at least gold, aluminum, silver, copper, or chromium coated with gold.

20. The method of claim 18, wherein the n-type layer is at least cesium carbonate, calcium acetylacetonate, or cesium fluoride.

21. The method of claim 18, wherein the conducting oxide layer is at least indium tin oxide or fluorinated tin oxide and wherein the conducting oxide layer is at least sputtered or thermal spray-coated on top of the n-type layer.

22. The method of claim 18, further comprising depositing a metal layer of at least gold or silver on top of the n-type layer by evaporation that is less than 20 nanometers thick.

23. The method of claim 18, wherein forming the organic active layer further comprises thermal annealing, solvent annealing or adding additives for improving morphology and enhancing carrier mobility, where the transparent substrate, transparent anode and the organic active layer are treated at a temperature range of about 70-180° Celsius.

24. A translucent solar cell comprising:
a transparent substrate having a bottom surface and a top surface;
a first translucent electrode on the top surface of the substrate, the first translucent electrode being a transparent conductive oxide layer and an n-type interfacial layer, wherein the first translucent electrode is the cathode;
a second translucent electrode made of a transparent conducting oxide layer and having an interfacial layer, wherein the second translucent electrode is the anode;
a transparent active layer made of a substantially organic material between the translucent anode and the translucent cathode.

25. A method for fabricating translucent solar cells, the method comprising:
providing a transparent substrate:
forming a transparent cathode on top of the transparent substrate, the forming process including the steps of:
depositing a transparent conducting oxide layer on the transparent substrate;
depositing an n-type interfacial layer on the transparent conducting oxide layer by solution processing or thermal evaporation; and annealing the transparent cathode and the transparent substrate within a temperature range of about 70-180° Celsius;
forming at least one organic active layer on the transparent cathode, wherein the organic active layer is deposited by solution processing and having a mix of at least one type of donor and at least one type of acceptor molecules, the organic active layer having a lowest unoccupied molecular orbital energy level being substantially similar to the n-type layer of the transparent cathode;
forming a transparent anode on the organic layer, the forming process including the steps of;
depositing a transition metal oxide layer by solution processing, the transition metal oxide having a work function substantially similar to a highest occupied molecular orbital energy level of the organic active layer; and
depositing a transparent conducting oxide layer onto the transition metal oxide layer.

26. The method of claim 25, wherein the transition metal oxide is at least vanadium pentoxide, molybdenum oxide or tungsten oxide and, wherein the transition metal oxide layer is of a thickness less than 30 nanometers.

27. The method of claim 25, wherein the conducting oxide layer is at least indium tin oxide or fluorinated tin oxide, wherein the conducting oxide layer is at least sputtered or thermal spray-coated on top of the n-type layer.

28. The method of claim 25, wherein the n-type layer is at least cesium carbonate, calcium acetylacetonate, or cesium fluoride.

29. A method for fabricating translucent solar cells, the method comprising:
providing a transparent substrate;
forming a transparent cathode on top of the transparent substrate, the forming process including the steps of:
depositing a transparent conducting oxide layer on the transparent substrate;
depositing an n-type layer on the transparent conducting oxide layer by solution processing or thermal evaporation; and
annealing the transparent cathode and the transparent substrate within a temperature range of about 70-180° degrees Celsius;
depositing at least one organic active layer on the transparent cathode, wherein the organic active layer is deposited by solution processing, the at least one organic active layer having a mix of donor and acceptor molecules and having a highest occupied molecular orbital energy level being substantially similar to the n-type layer of the transparent cathode;
forming a transparent anode on the organic layer, the forming process including the steps of:
depositing a transition metal oxide layer by solution processing, the transition metal oxide having a work function substantially similar to a highest occupied molecular orbital energy level of the organic active layer; and
depositing at least one metal film being at least gold or silver on the transition metal oxide layer.

30. The method of claim 29, wherein the n-type layer is at least cesium carbonate, calcium acetylacetonate or cesium fluoride.

31. The method of claim 29, wherein the transition metal oxide is at least vanadium pentoxide, molybdenum oxide or tungsten oxide and is of a thickness less than 30 nanometers.

32. The method of claim 29, wherein the conducting oxide layer is at least indium tin oxide or fluorinated tin oxide and is at least sputtered or thermal spray-coated on top of the n-type layer.
